(19) United States
(12) Patent Application Publication
(10) Pub. No.: US 2023/0197526 A1
(43) Pub. Date: Jun. 22, 2023

(54) REDUCED DIFFUSION BREAK STRUCTURE

(71) Applicant: International Business Machines Corporation, Armonk, NY (US)

(72) Inventors: Ruilong Xie, Niskayuna, NY (US); Veeraraghavan S. Basker, Schenectady, NY (US); Kangguo Cheng, Schenectady, NY (US); Junli Wang, Slingerlands, NY (US)

(21) Appl. No.: 17/559,296

(22) Filed: Dec. 22, 2021

(51) Int. Cl. H01L 21/8238; H01L 29/66; H01L 21/762; H01L 27/092

(52) U.S. Cl. CPC H01L 21/823864; H01L 29/6656; H01L 29/66545; H01L 21/823814; H01L 21/823878; H01L 21/76224; H01L 27/092

(57) ABSTRACT

Embodiments of the present disclosure provide a semiconductor structure including a first sidewall spacer positioned between a first gate terminal and a first source/drain terminal of a first active device. The first sidewall spacer includes a first L-shaped spacer and a first outer spacer. The L-shaped spacer having a base portion and a vertical portion vertically extended, parallel to the first outer spacer, to a top portion of a first inter dielectric layer (IDL). A RDB dielectric, having a reduced width less than a width of the first gate terminal. The RDB dielectric vertically extends from the top portion of the IDL into the substrate. The RDB dielectric is separated from the first source/drain terminal by first RDB spacer, the first RDB spacer includes a first upper spacer. The first RDB spacer has a reduced width less that the first sidewall spacer width.

### BACKGROUND

Aspects of the present disclosure relate generally to the field of isolation structure formation for devices such as complimentary metal-oxide semiconductor (CMOS) and, more particularly to single diffusion breaks. Decisions regarding integrate circuits are progressively being driven not only by manufacturing costs and efficiency, but also by device density and scalability. Single diffusion breaks are often used to reduce the circuit area consumed and to enable the formation high density integrated circuits. Unfortunately, single diffusion breaks are often challenging to manufacture while still consuming a significant amount of chip space.

### SUMMARY

A first aspect of the present disclosure provides a reduced diffusion break structure (RDB) structure including: a first sidewall spacer positioned between a first gate terminal and a first source/drain terminal of a first active device, wherein the first sidewall spacer includes a first L-shaped spacer and a first outer spacer, the L-shaped spacer having a base portion horizontally extended from the first gate terminal to the first source/drain terminal and a vertical portion vertically extended, parallel to the first outer spacer, to a top portion of a first inter dielectric layer (IDL); a RDB dielectric, having a first reduced width less than a width of the first gate terminal, vertically extended from the top portion of the first IDL into a substrate, wherein the RDB dielectric is separated from the first source/drain terminal by a first RDB spacer, the first RDB spacer having a first upper spacer, wherein the first RDB spacer has a second reduced width less that a width of the first sidewall spacer.

A second aspect of the present disclosure provides a method of forming a RDB structure, the method including: forming a first dummy gate and a second dummy gate on a substrate, wherein an exposed portion of substrate is between the first dummy gate and the second dummy gate; depositing a first spacer liner over the first dummy gate, the second dummy gate, and the exposed portion of substrate between the first dummy gate and the second dummy gate; forming a RDB dielectric structure between the first dummy gate and the second dummy gate; depositing a second spacer liner vertically along the RDB dielectric structure, the first dummy gate, and the second dummy gate; forming a set of source/drain terminals for each of the first dummy gate and the second dummy gate, wherein the set of source/drain terminals are embedded adjacent to the first dummy gate and the second dummy gate, respectively; and replacing each the first dummy gate and the second dummy gate with a metal gate terminal.

A third aspect of the present disclosure provides a semiconductor structure, the semiconductor structure including: a reduced diffusion break (RDB) structure having a RDB dielectric structure vertically extended into a substrate from a top portion of the inter dielectric layer (IDL), wherein the RDB dielectric structure is configured between a first RDB spacer and a second RDB spacer; a first sidewall spacer positioned between a first gate terminal and a first source/drain terminal of a first active device, wherein the first sidewall spacer includes a first L-shaped spacer and a first outer spacer, the L-shaped spacer having a base portion horizontally extended from the first gate terminal to the first source/drain terminal and a vertical portion vertically extended parallel to the first outer spacer a top portion of an inter dielectric layer (IDL); and a second sidewall spacer positioned between a second gate terminal and a second source/drain terminal of a second active device, wherein the second sidewall spacer includes a second L-shaped spacer and a second outer spacer, the second L-shaped spacer having a base portion horizontally extended from the second gate terminal to the second source/drain terminal and a vertical portion vertically extended parallel to the second outer spacer to a top portion of a second IDL.

### BRIEF DESCRIPTION OF THE DRAWINGS

The drawings included in the present disclosure are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 depicts a schematic view of a conventional semiconductor structure.

FIG. 2 depicts a cross-sectional view of a reduced single diffusion break in a semiconductor structure, in accordance with embodiments of the present disclosure.

FIG. 3A schematically illustrates a process flow for forming a reduced diffusion break, in accordance with embodiments of the present disclosure.

FIG. 3B schematically illustrates a continuation of the process flow for forming a reduced diffusion break, in accordance with embodiments of the present disclosure.

FIG. 3C schematically illustrates another continuation of the process flow for forming a reduced diffusion break, in accordance with embodiments of the present disclosure.

FIG. 3D schematically illustrates another continuation of the process flow for forming a reduced diffusion break, in accordance with embodiments of the present disclosure.

FIG. 3E schematically illustrates another continuation of the process flow for forming a reduced diffusion break, in accordance with embodiments of the present disclosure.

FIG. 3F schematically illustrates another continuation of the process flow for forming a reduced diffusion break, in accordance with embodiments of the present disclosure.

FIG. 3G schematically illustrates another continuation of the process flow for forming a reduced diffusion break, in accordance with embodiments of the present disclosure.

FIG. 3H schematically illustrates another continuation of the process flow for forming a reduced diffusion break, in accordance with embodiments of the present disclosure.

FIG. 3I schematically illustrates another continuation of the process flow for forming a reduced diffusion break, in accordance with embodiments of the present disclosure.

FIG. 4 illustrates a high-level block diagram of an example computer system that may be used in implementing one or more of the methods, tools, and modules, and any related functions, described herein, in accordance with embodiments of the present disclosure.

While the embodiments described herein are amenable to various modifications and alternative forms, specifics thereof have been shown by way of example in the drawings and will be described in detail. It should be understood, however, that the particular embodiments described are not to be taken in a limiting sense. On the contrary, the intention is to cover all modifications, equivalents, and alternatives falling within the spirit and scope of the disclosure.

### DETAILED DESCRIPTION

Aspects of the present disclosure relate generally to the field of isolation structure formation for devices such as complimentary metal-oxide semiconductor (CMOS) and, more particularly to single diffusion break (SDB) structure.

A SDB structure is an isolation structure in semiconductor technology that allows for the formation of high density integrated circuit technology by reducing the amount of circuit area consumed. Often the SDB acts as an isolation barrier between semiconductor components (e.g., between two transistors). Though traditional SDB structures have been effective, the size associated with traditional SDB structures has remained constant despite many the area reduction of many semiconductor devices. For example, traditional SDB structures are often designed with a width of the sum of the gate length and 2 times of the width of the gate spacer (e.g., if the gate length is 18 nm, and the gate spacer width is 6 nm, the SDB size is approximately 30 nm). As such, there is a desire for a reduced diffusion break that may continue to aid in scaling (e.g., CMOS scaling). The present disclosure provides solutions for the structure and formation of a reduced isolation structure (e.g., reduced diffusion break) that requires less area than traditional SBD structures while still isolating two active devices.

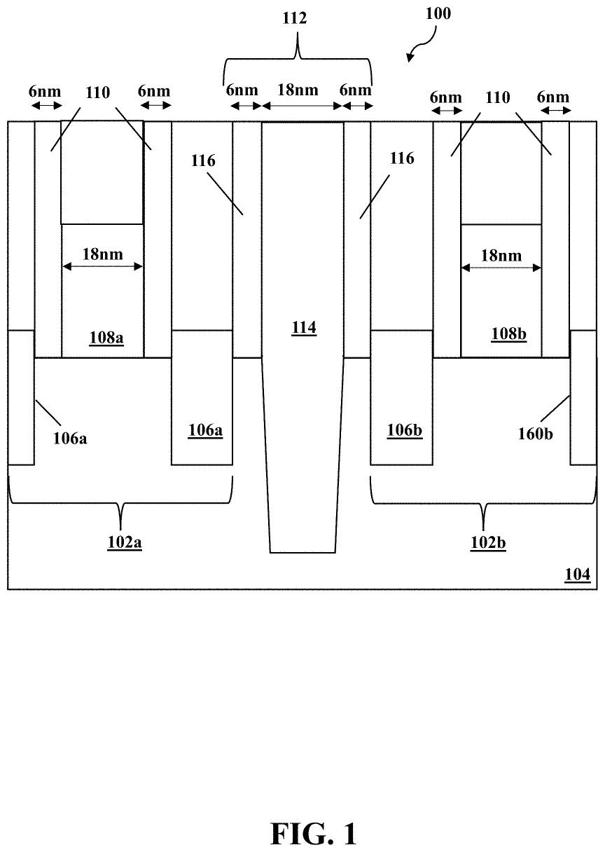

Referring to FIG. 1, a conventional semiconductor structure 100 is depicted as an example to emphasize the structural and operational differences relative to embodiments of the present disclosure, and semiconductor structural elements included therein. Conventional semiconductor 100 may include first transistor device 102a and second transistor device 102b formed within substrate 104. Each first transistor device 102a and second transistor device 102b may include source/drain regions 106a and 106b, and a gate structure 108a and 108b. Each of the source/drain regions 106a and 106b associated with first transistor device 102a and second transistor device 102b (e.g., and other semiconductor components not shown) may be separated by spacers 110.

First transistor device 102a and second device 102b may be electrically separated by a SDB structure 112. SDB structure 112 acts as an isolation area to block parasitic elements between first transistor device 102a and second transistor device 102b. This SDB structure 112 includes SDB dielectric 114, that extends into substrate 104, and SDB spacers 116. SDB spacers 116 separate source/drain regions 106a and 106b, respectively, from SDB dielectric 114.

Due to conventional formation of SDB structures, such as SDB structure 112, in semiconductor structures, SDB dielectric 114 is approximately the width of a gate structure. For example, a gate structure can be approximately 18 nm for advanced FINFET technology, and can be slightly smaller for nanowire or nanosheet technology (e.g., gate structures 108a and 108b). SDB spacers 116 are traditionally the same or approximately the same width and composition as spacers 110. The conventional SDB spacers 116 and spacers 110 depicted in FIG. 1 are approximately 6 nm wide (or between 5 to 15 nm). In some implementations, spacers 110 and SDB spacers 116 are often formed during the same process. The isolation footprint of SDB structure 112 can be measured by adding the width of SDB spacers 116 and the width of the SDB dielectric 114 for a total isolation footprint of 30 nm.

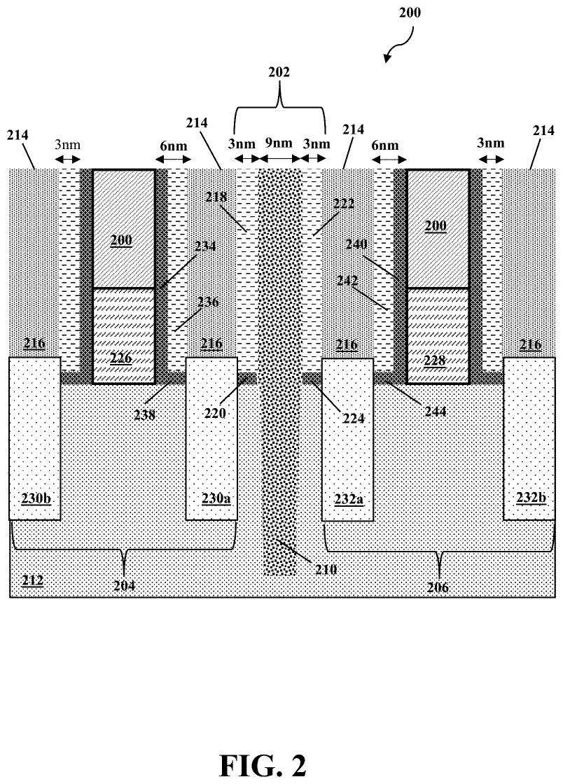

Turning to FIG. 2, a cross-sectional view of a semiconductor structure having a reduced diffusion break (RDB) structure 202 is depicted. RDB structure 202 may be configured to electrically isolate first active device 204 from second active device 206 and vice versa, while minimizing the total amount of area such isolating devices usually consume. For example, while many traditional SBD structures, such as those depicted in FIG. 1, have isolation footprints approaching 30 nm or more, in some embodiments RDB structure 202 may have a reduced isolation footprint of approximately 15 nm. By electrically isolating first active device 204 from second active device 206, any parasitic components resulting from either device are prevented from affecting the other neighboring device. Though embodiments contemplated herein may make reference to various transistor components (e.g., source terminal, drain terminal, and gate terminal) while discussing first and second active devices 204 and 206, respectively, in semiconductor structure 200, RDB structure 202 may isolate any active device from another active device. These active devices may include, but are not limited to, various types of transistors, diodes, power supplies, amplifiers, transmitters, or any other electrical component that requires an energy sources to operate. In addition, though semiconductor structure 200 only depicts first active device 204 and second active device 206 with a single RDB structure 202, semiconductor structure 200 may be configured to include any number of active devices and RDB structures that may be needed.

RDB structure 202 may include a RDB dielectric structure 210 and first RDB spacer and second RDB spacer configured on either side of the RDB dielectric structure 210. RDB dielectric structure 210 may be centrally positioned between the first RDB spacer and the second RDB spacer. In some embodiments, RDB dielectric structure 210 may vertically extend from a predetermined depth within substrate 212 to a vertical height approximately the height of a top portion 214 of interlayer dielectric (IDL) layer 216. In embodiments, RDB dielectric structure 210 may have first reduced width that is less than the width of a gate terminal. For example, RDB dielectric structure 210 may have a width of approximately 9 nm while first gate terminal 226 associated with first active device 204 and second gate terminal 228 associated with second active device 206 respectively, may each have a gate width approaching 18 nm. While RDB dielectric structure 210 may be comprised of any available dielectric material, examples of possible dielectric material include SiN, SiC, and SiCO.

In embodiments, first and second RDB spacer may each vertically extend from the top of substrate 212 to a vertical height approximately the height of a top portion 214 of a first interlayer dielectric (IDL) layer 216 on either side of RDB dielectric structure 210. Based on the design parameters of semiconductor structure 200, the first and second RDB spacer may each have a reduced width (e.g., second reduced width) of approximately 3 nm. In some embodiments, each RDB spacer may include a upper spacer and/or a base spacer. For example, first RDB spacer may include first upper spacer 218 and first base spacer 220 and second RDB spacer may include second upper spacer 222 and second base spacer 224. First base spacer 220 may be positioned directly beneath first upper spacer 236 and directly above substrate 212. First base spacer may then extend horizontally from RDB dielectric structure 210 to first source/drain terminal 230a associated with first active device 204. While second base spacer 224 is similarly also positioned directly beneath second upper spacer 242 and directly above substrate 212, second base spacer 224 extends (e.g., in the opposite direction) horizontally toward second source/drain terminal 232a associated with second active device 206. To provide a complete illustration of first active device 204 and second active device 206, first and second active device 204 and 206 may each include a corresponding source/drain terminal (e.g., first corresponding source/drain terminal 230b and second corresponding source/drain terminal 232b). In embodiments, directly above each first source/drain terminal 230a and second source/drain terminal 232a (and the associated corresponding source/drain terminals 230b and 232b) is an ILD layer 216 (e.g., first ILD layer and second IDL layer) that extends from the top of the respective source/drain terminal and extends to the top of semiconductor structure 200 (e.g., to top portion 214).

In embodiments, semiconductor device 200 may also include first sidewall spacer positioned between first gate terminal 226 and a first source/drain terminal 230a of a first active device 204. First sidewall spacer may include a first L-shaped spacer 234 and first outer spacer 236. In embodiments, L-shaped spacer 234 may be configured to have a bottom portion 238 that horizontally extends from first gate terminal 226 to first source/drain terminal 230a. The vertical portion of L-shaped space 234 may vertically extended, parallel to first outer spacer 236, to a vertical height approximately the height a top portion 214 of a IDL layer 216 (e.g., a first IDL layer). In some embodiment, the first RDB spacer may have a reduced width (e.g., second reduced width) that is less than the width of the first sidewall spacer (e.g., the combined width of each the first outer spacer 236 and the L-shaped spacer 234).

In embodiments, semiconductor device 200 may also include a second sidewall spacer. The second sidewall spacer may be positioned between second gate terminal 228 and second source/drain terminal 232a of second active device 206. The second sidewall spacer may include a second L-shaped spacer 240 and second outer spacer 242. In embodiments, second L-shaped spacer 240 may have bottom portion 244 that horizontally extends from second gate terminal 228 to second source/drain terminal 232a and a vertical portion that extends vertically, parallel to second outer spacer 242 to a vertical height approximately the height a top portion 214 of a IDL layer 216 (e.g., a second IDL layer). In embodiments, second RDB spacers may have a reduced width (e.g., third reduced width) that is less than the width of second sidewall spacer (e.g., the combined width of each the second outer spacer 242 and the L-shaped spacer 240). In embodiments contemplated herein, the widths of RDB dielectric structure 210, the first RDB spacer, and the second RDB spacer, when combined, have a combined reduced width that is less than a combined width of either first gate terminal 226 or second gate terminal 228. Accordingly, the RDB structure, such as that contemplated herein, can have an isolation footprint of approximately 15 nm. The aforementioned structure of semiconductor structure 200 results in approximately a 50% reduction in area needed to form an isolation break than the amount of area needed to form traditional SDB structures.

In some embodiments, the material comprising the base spacers (e.g., first base spacer 220 and second base spacer 224) associated with the first and second RDB spacers, is the same material comprising the L-shaped spacers (e.g., first L-shaped spacer 234 and L-shaped spacer 244) of the first and second sidewall spacers. This material may be comprised of a variety of materials including, but not limited to, SiBCN, SiOCN, and SiCO. In some embodiments, the material comprising the outer spacers (e.g., first outer spacer 236 and second outer spacer 242) associated with first and second sidewall spacer is the same material of the upper spacers (e.g., first upper spacer 218 and second upper spacer 222) associated with the RDB spacers.

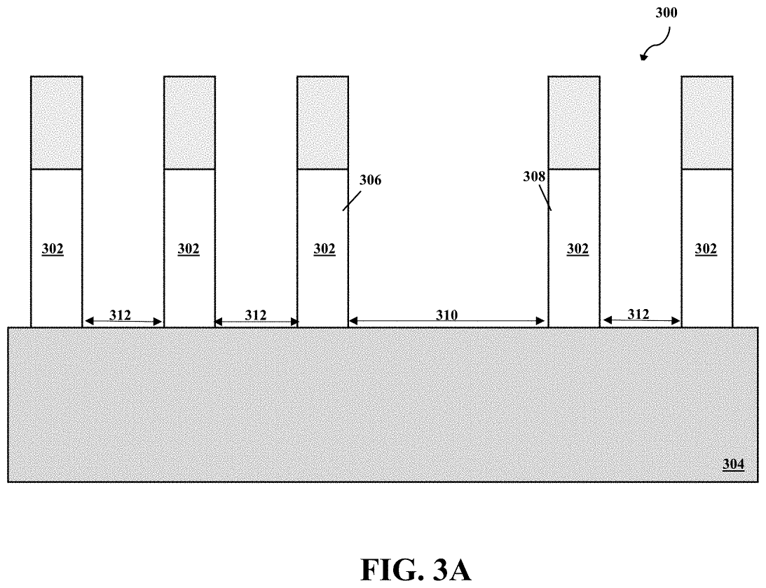

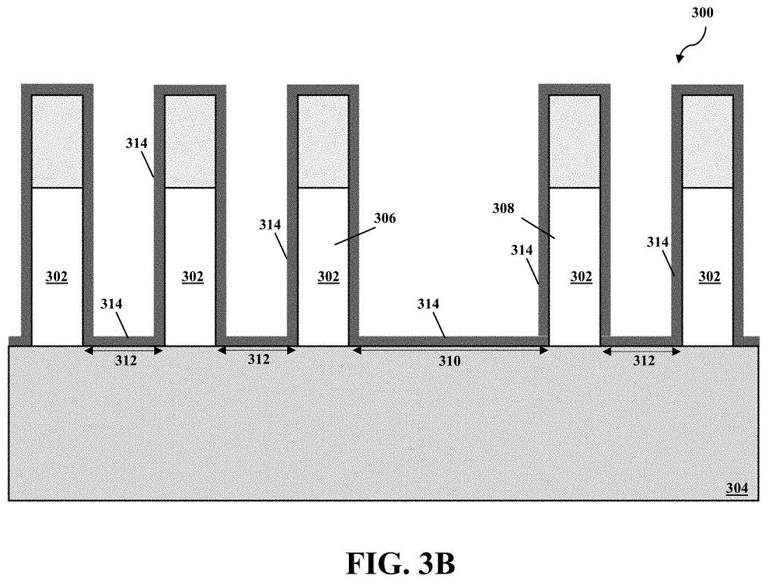

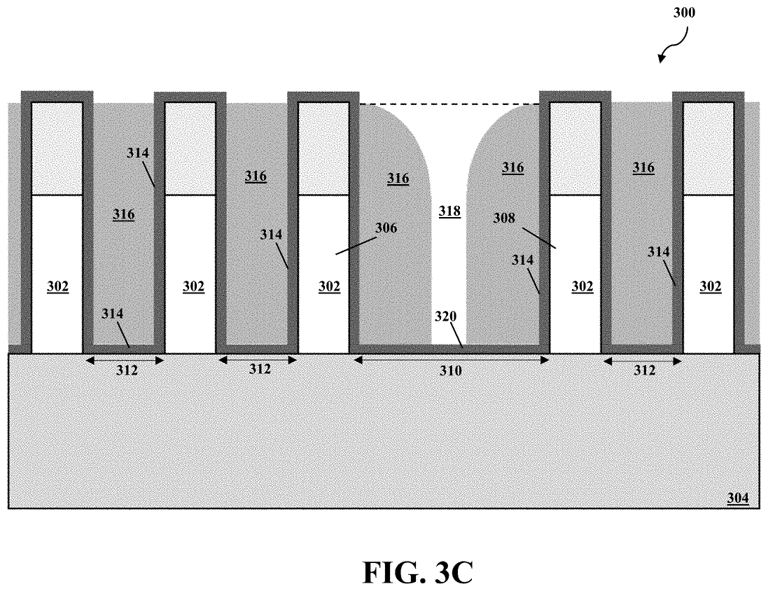

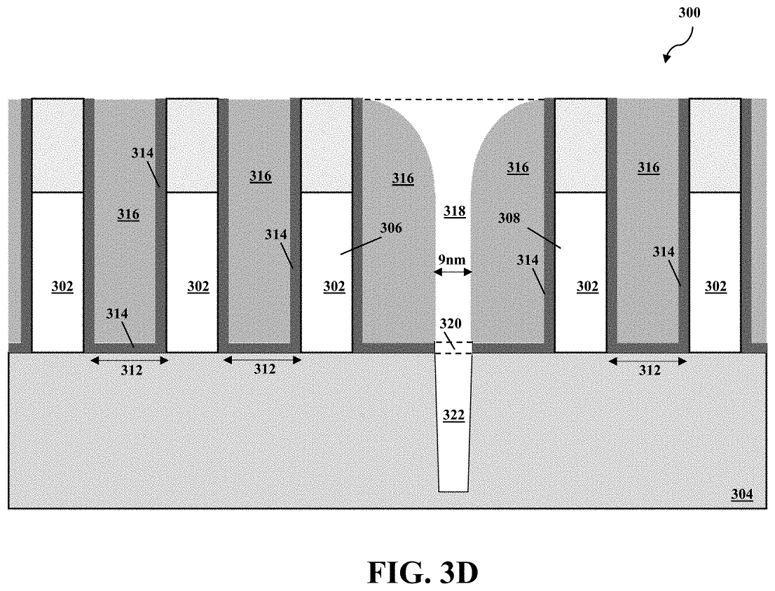

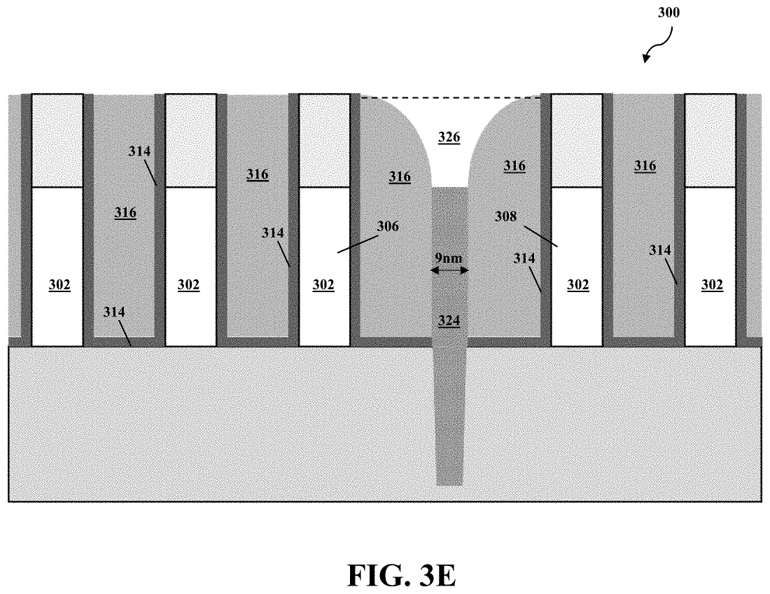

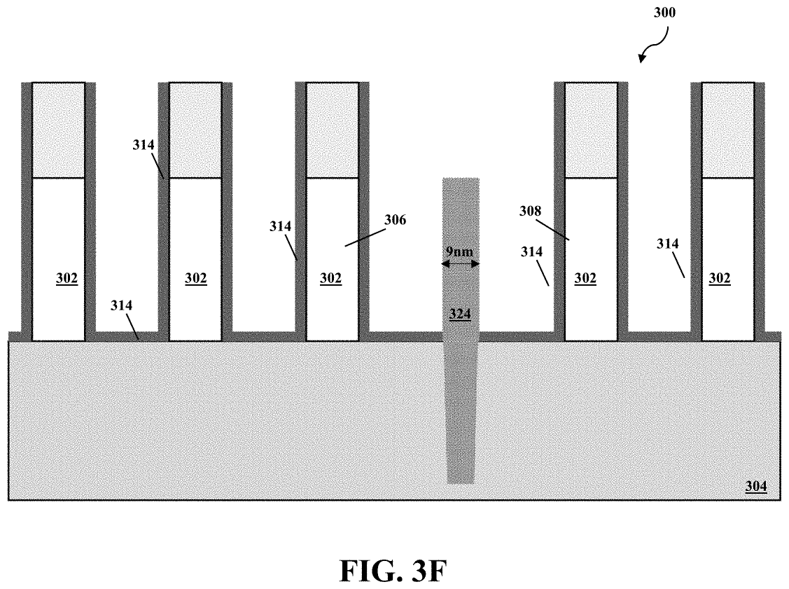

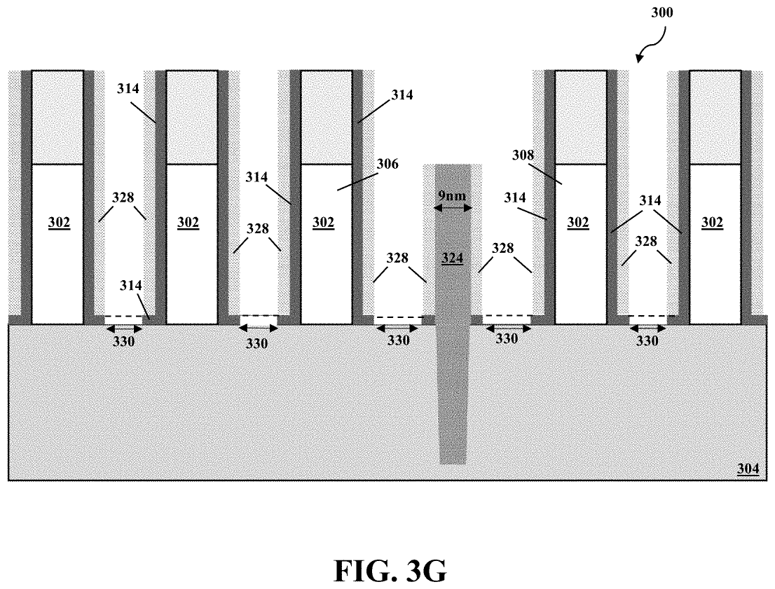

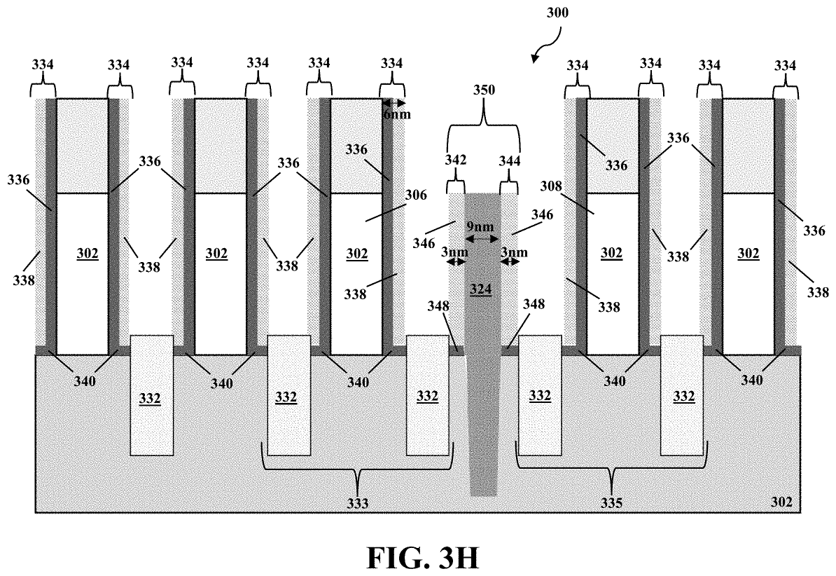

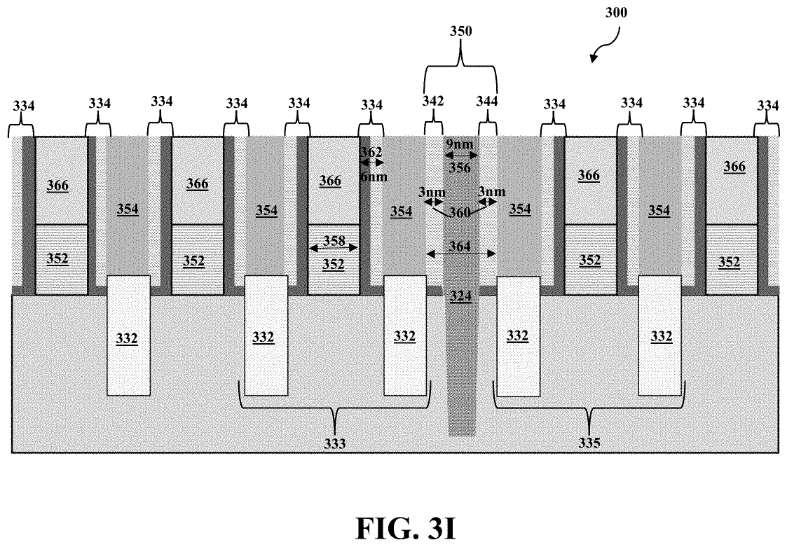

FIGS. 3A-3I, schematically illustrate a process flow for forming a RDB structure in a semiconductor structure, such as RDB structure 202 discussed in reference to FIG. 2, in accordance with embodiments of the present disclosure.

In embodiments, semiconductor structure 300 having a RDB structure may have a number of dummy gates 302 formed on substrate 304. In such embodiments, the dummy gates may be patterned with variable pitch. While semiconductor structure 300 may have any number of dummy gates 302 (e.g., FIG. 3A depicts five separate dummy gates 302), semiconductor structure 300 must have at least two dummy gates to form the RDB structure. For example, first dummy gate 306 and second dummy gate 308 may be formed on substrate 304 leaving an exposed portion 310 of substrate 304. In embodiments having more than first dummy gate 306 and second dummy gate 308, there may be an exposed portion 312 of substrate 304 between each of the number of dummy gates 304. However, in embodiments contemplated herein, the exposed portion 310 between first dummy gate 306 and second dummy gate 308 may be larger than the widths of exposed substrate 312 between other dummy gates 304. Exposed portion 310 of substrate 304 may be larger than a single gate pitch separation width and less than a double gate pitch width.

Turning now to FIG. 3B, first spacer liner 314 is deposited over dummy gates 302 (e.g., including first dummy gate 306 and second dummy gate 308) and at least exposed portion 310 of substrate 304. First spacer liner 314 may be evenly deposited over the aforementioned structures. For example, first spacer liner 314 may be deposited in such a way to be between 2 to Shave approximately a 3 nm width (e.g., ranging from a width of 2 to 5 nm) throughout semiconductor structure 300. First spacer liner 314 may be comprised of various materials including, but not limited to SiBCN, SiOCN, and SiCO. Referring back to FIG. 2, L-shaped spacers 238 and 244 as well as base spacers 220 and 224 are ultimately formed from first spacer liner 314.

Turning now to FIG. 3C, the initial stages of forming a RDB structure (e.g., RDB structure 202) between first dummy gate 306 and second dummy gate 308. In embodiments, conformal sacrificial liner 316 may be deposited on top of first spacer liner 314. Conformal sacrificial liner 316 may be comprised of a variety of materials, such as TiO, and SiO₂. The conformal sacrificial liner 316 may be etched between first dummy gate 306 and second dummy gate 308 to first spacer liner 314. This etching may form a first portion (e.g., first amount) of RDB dielectric recess 318. The first portion of RDB dielectric recess 318 may be approximately 9 nm wide and may be centrally positioned between first dummy gate 306 and second dummy gate 308. This etching process results in exposing an exposed portion of first spacer liner 320 positioned directly above substrate 302.

Turning now to FIG. 3D, the formation of a RDB structure (e.g., RDB structure 202) is continued. The exposed portion of first space liner 320 may be removed to breakthrough to substrate 304. During this process the first space liner 314 may also be removed from the top of each dummy gate 304. A second etching process may be used to remove a portion of substrate to form a second portion (e.g., second amount) of the RDB dielectric recess 322. The second amount of the RDB dielectric recess 322 may have a predetermined substrate depth, based on semiconductor structure 300 design parameters.

Turning to FIG. 3E, the formation of a RDB structure (e.g., RDB structure 202) is continued. In embodiments, after the RDB dielectric recess (e.g., first portion of RDB dielectric recess 318 and second portion of RDB dielectric recess 322) is formed, the RDB dielectric recess may be filled with an appropriate dielectric material, such as SiN, SiC, and SiCo. Once the RDB dielectric recess is sufficiently filled, RDB dielectric structure 324 is formed (See FIG. 3D RDB dielectric structure 324). In some embodiments, the RDB dielectric structure 324 may be etched back a predetermined amount 326. In these embodiments, such etching may be based on semiconductor structure 300 design parameters.

Turning to FIG. 3F, the formation of a RDB structure (e.g., RDB structure 202) is continued. In embodiments, after RDB dielectric structure 324 is formed, the conformal sacrificial liner is removed, as depicted in FIG. 3F.

Turning to FIG. 3G, the formation of a RDB structure (e.g., RDB structure 202) is continued. In embodiments, second spacer liner 328 may be deposited on semiconductor structure 304. In some embodiments, second spacer liner 328 may be deposited vertically along each side of the RDB dielectric structure 324 and dummy gates 304 (e.g., the first dummy gate 306 and second dummy gate 308). When deposited, second spacer liner 328 may have a particular designed width, such as a width of 3 nm (e.g., ranging from a width from 3 to 10 nm). In some embodiments, a portion of first spacer liner 314 may be removed between each of dummy gates 302 to expose portion 330 of substrate 304.

Turning to FIG. 3H, the formation of a RDB structure (e.g., RDB structure 202) is continued. In embodiments source/drain terminals 332 (e.g., set of source/drain terminals) associated with each intended active device (e.g., first active device 333 and second active device 335) may be formed (e.g., using FIN recession and epitaxial growth) in semiconductor structure 300. The source/drain terminals 332 may be at least partially embedded in substrate 302 adjacent to each of the dummy gates 302 (e.g., first dummy gate 306 and second dummy gate 308). For example, a source/drain terminal 332 of the set of source/drain terminals associated first dummy gate 306 may be formed using epitaxial growth between the sidewall spacer (e.g., first sidewall spacer) and RDB structure (e.g., RDB structure 200) and extending vertically from the substrate.

In embodiments, during the deposition of second space liner 328, one or more side wall spacers 334 (e.g., first side wall spacer and second side wall spacer discussed in FIG. 2) are formed adjacent to each side of the number of dummy gates 304. Each of sidewall spacer 334 may include an L-shaped spacer 336, composed of first spacer liner 314, and an outer spacer 338, composed of second spacer liner 328. Each L-shaped spacer 336 may be configured to have a bottom portion 340 that horizontally extends from dummy gate 304 to the respective source/drain terminal 332. The vertical portion of L-shaped space may vertically extend, parallel to the outer spacer 338.

In embodiments, during the deposition of second space liner 328, first RDB spacer 342 and second RDB spacer 344 may be formed. Both first RDB spacer 342 and second RDB spacer 344 may extending vertically along the set of exposed walls of RDB dielectric structure 324 directly above the substrate 304. First RDB spacer 342 and second RDB spacer 344 may each include an upper spacer 346, composed of second spacer liner 328, and a base spacer 348, composed of first spacer liner 314. With the formation of first RDB spacer 342 and second RDB spacer 344 adjacent to RDB dielectric structure 324, RDB structure 350 is formed.

Turning to FIG. 3I, the formation of a RDB structure (e.g., RDB structure 202) in semiconductor structure 300 is continued. While all structures and their respective identifiers, unless otherwise stated, referenced in discussion of FIGS. 3A-3H are carried forward to FIG. 3I, some identifiers are not depicted in FIG. 3I for the sake of clarity.

In embodiments, an ILD layer 354 may be deposited over each of the source/drain terminals 332 that may extend to the top portion of the dummy gates 304 through CMP. Each dummy gate 304 (e.g., first dummy gate 306 and second dummy 308) may then be replaced with metal gate terminals 352. While one or more methods may be used replace dummy gates 304 with metal gate terminals 352, one such method may use an wet or RIE etch to remove the dummy gate, followed by depositing gate stack including gate dielectric and gate electrode to form the replacement metal gate process. In some embodiments, the replacement gate 352 is recessed, followed by an gate dielectric cap 366 formation.

In embodiments, RDB dielectric structure 324 may have a reduced width 356 (e.g., first reduced width) that is less than a width 358 of a gate terminal (e.g., first gate terminal). In such embodiments, first RDB spacer 342 and second RDB spacer 344 each have a reduced width 360 (e.g., second reduced width) that is less than the width 362 of the sidewall spacer (e.g., first sidewall spacer). Accordingly, semiconductor structure 300 has a RDB structure 350 having a total combined isolation footprint 364 that is approximately 15 nm (e.g., combining a 3 nm reduced width associated with first RDB spacer 342, a 3 nm reduced width associated with second RDB spacer 344, and a 9 nm reduced width associated with RDB dielectric structure 324). RDB structure 350's isolation footprint 364 is approximately half the total area of traditional SDB structures (e.g., SDB structure 112 of FIG. 1).

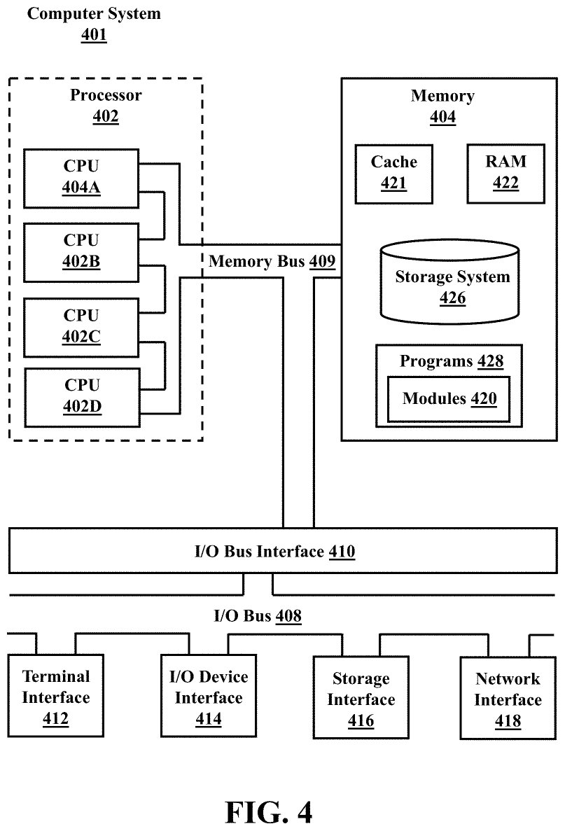

FIG. 4, illustrated is a high-level block diagram of an example computer system 401 that may be used in implementing one or more of the methods, tools, and modules, and any related functions, described herein (e.g., using one or more processor circuits or computer processors of the computer), in accordance with embodiments of the present disclosure. In some embodiments, the major components of the computer system 401 may comprise one or more CPUs 402, a memory subsystem 404, a terminal interface 412, a storage interface 416, an I/O (Input/Output) device interface 414, and a network interface 418, all of which may be communicatively coupled, directly or indirectly, for inter-component communication via a memory bus 409, an I/O bus 408, and an I/O bus interface unit 410.

The computer system 401 may contain one or more general-purpose programmable central processing units (CPUs) 402A, 402B, 402C, and 402D, herein generically referred to as the CPU 402. In some embodiments, the computer system 401 may contain multiple processors typical of a relatively large system; however, in other embodiments the computer system 401 may alternatively be a single CPU system. Each CPU 402 may execute instructions stored in the memory subsystem 404 and may include one or more levels of on-board cache.

System memory 404 may include computer system readable media in the form of volatile memory, such as random access memory (RAM) 422 or cache memory 424. Computer system 401 may further include other removable/non-removable, volatile/non-volatile computer system storage media. By way of example only, storage system 426 can be provided for reading from and writing to a non-removable, non-volatile magnetic media, such as a “hard drive.” Although not shown, a magnetic disk drive for reading from and writing to a removable, non-volatile magnetic disk (e.g., a “floppy disk”), or an optical disk drive for reading from or writing to a removable, non-volatile optical disc such as a CD-ROM, DVD-ROM or other optical media can be provided. In addition, memory 404 can include flash memory, e.g., a flash memory stick drive or a flash drive. Memory devices can be connected to memory bus 409 by one or more data media interfaces. The memory 404 may include at least one program product having a set (e.g., at least one) of program modules that are configured to carry out the functions of various embodiments.

One or more programs/utilities 428, each having at least one set of program modules 490 may be stored in memory 404. The programs/utilities 428 may include a hypervisor (also referred to as a virtual machine monitor), one or more operating systems, one or more application programs, other program modules, and program data. Each of the operating systems, one or more application programs, other program modules, and program data or some combination thereof, may include an implementation of a networking environment. Programs 428 and/or program modules 440 generally perform the functions or methodologies of various embodiments.

Although the memory bus 409 is shown in FIG. 4 as a single bus structure providing a direct communication path among the CPUs 402, the memory subsystem 404, and the I/O bus interface 410, the memory bus 409 may, in some embodiments, include multiple different buses or communication paths, which may be arranged in any of various forms, such as point-to-point links in hierarchical, star or web configurations, multiple hierarchical buses, parallel and redundant paths, or any other appropriate type of configuration. Furthermore, while the I/O bus interface 410 and the I/O bus 408 are shown as single respective units, the computer system 401 may, in some embodiments, contain multiple I/O bus interface units 410, multiple I/O buses 408, or both. Further, while multiple I/O interface units are shown, which separate the I/O bus 408 from various communications paths running to the various I/O devices, in other embodiments some or all of the I/O devices may be connected directly to one or more system I/O buses.

In some embodiments, the computer system 401 may be a multi-user mainframe computer system, a single-user system, or a server computer or similar device that has little or no direct user interface, but receives requests from other computer systems (clients). Further, in some embodiments, the computer system 401 may be implemented as a desktop computer, portable computer, laptop or notebook computer, tablet computer, pocket computer, telephone, smartphone, network switches or routers, or any other appropriate type of electronic device.

It is noted that FIG. 4 is intended to depict the representative major components of an exemplary computer system 401. In some embodiments, however, individual components may have greater or lesser complexity than as represented in FIG. 4, components other than or in addition to those shown in FIG. 4 may be present, and the number, type, and configuration of such components may vary.

As discussed in more detail herein, it is contemplated that some or all of the operations of some of the embodiments of methods described herein may be performed in alternative orders or may not be performed at all; furthermore, multiple operations may occur at the same time or as an internal part of a larger process.

The present disclosure may be a system, a method, and/or a computer program product at any possible technical detail level of integration. The computer program product may include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present disclosure has been described in terms of specific embodiments, it is anticipated that alterations and modification thereof will become apparent to the skilled in the art. Therefore, it is intended that the following claims be interpreted as covering all such alterations and modifications as fall within the true spirit and scope of the disclosure.

What is claimed is:

1. A reduced diffusion break (RDB) structure comprising:
a first sidewall spacer positioned between a first gate terminal and a first source/drain terminal of a first active device, wherein the first sidewall spacer includes a first L-shaped spacer and a first outer spacer, the L-shaped spacer having a base portion horizontally extended from the first gate terminal to the first source/drain terminal and a vertical portion vertically extended, parallel to the first outer spacer, to a top portion of a first inter dielectric layer (IDL); and
a RDB dielectric, having a first reduced width less than a width of the first gate terminal, vertically extended from the top portion of the first IDL into a substrate, wherein the RDB dielectric is separated from the first source/drain terminal by a first RDB spacer, the first RDB spacer having a first upper spacer, wherein the first RDB spacer has a second reduced width less that a width of the first sidewall spacer.

2. The RDB structure of claim 1, further comprising:
a second sidewall spacer positioned between a second gate terminal and a second source/drain terminal of a second active device, wherein the second sidewall spacer includes a second L-shaped spacer and a second outer spacer, the second L-shaped spacer having a base portion horizontally extended from the second gate terminal to the second source/drain terminal and a vertical portion vertically extended parallel to the second outer spacer to a top portion of a second IDL.

3. The RDB structure of claim 2, wherein the RDB dielectric structure vertically extends from the top portion of the second IDL into the substrate, wherein the RDB dielectric structure is separated from the second source/drain terminal by a second RDB spacer, the second RDB spacer having a second upper spacer, wherein the second RDB spacer has a third reduced width less than a width of the second sidewall spacer.

4. The RDB structure of claim 1, wherein the first RDB spacer further includes a first base spacer positioned directly beneath the first upper spacer of the first RDB spacer and extends from the first source/drain terminal to the RDB dielectric directly above the substrate.

5. The RDB structure of claim 4, wherein a material of the first base spacer and a material of the L-shaped spacer are the same material.

6. The RDB structure of claim 1, wherein the base portion of the first L-shaped spacer is positioned directly beneath the first outer spacer and above the substrate.

7. The RDB structure of claim 1, wherein a material of the first outer spacer and a material of the first upper spacer are the same material.

8. The RDB structure of claim 1, wherein the RDB dielectric structure, the first RDB spacer, and the second RDB spacer have a combined reduced width that is less than a combined width of the first gate terminal.

9. A method of forming a reduced diffusion break (RDB) structure, the method comprising:
forming a first dummy gate and a second dummy gate on a substrate, wherein an exposed portion of substrate is between the first dummy gate and the second dummy gate;
depositing a first spacer liner over the first dummy gate, the second dummy gate, and the exposed portion of substrate between the first dummy gate and the second dummy gate;
forming a RDB dielectric structure between the first dummy gate and the second dummy gate;
depositing a second spacer liner vertically along the RDB dielectric structure, the first dummy gate, and the second dummy gate;
forming a set of source/drain terminals for each of the first dummy gate and the second dummy gate, wherein the set of source/drain terminals are embedded adjacent to the first dummy gate and the second dummy gate, respectively; and
replacing each the first dummy gate and the second dummy gate with a metal gate terminal.

10. The method of claim 9, wherein the exposed portion of substrate between the first dummy gate and the second dummy gate is larger than a single gate pitch separation width and less than a double gate pitch width.

11. The method of claim 9, wherein forming the RDB dielectric structure between the first dummy gate and the second dummy gate, further includes:
depositing a conformal sacrificial liner on top of the first spacer liner;
etching, to the first spacer liner, a first amount of a RDB dielectric recess in the conformal sacrificial liner between the first dummy gate and the second dummy gate; and
exposing an exposed portion of the first spacer liner positioned directly above the substrate.

12. The method of claim 11, further including:
removing the exposed portion of the first spacer liner; and
etching a second amount of the RDB dielectric recess into the substrate, wherein the second amount of the RDB dielectric recess is based on a predetermined substrate depth.

13. The method of claim 12, further including:
filing the RDB dielectric recess with a dielectric to form the RDB dielectric structure.

14. The method of claim 9, wherein depositing the second space liner further includes:
forming a first sidewall spacer and a second sidewall spacer associated with the first dummy gate and the second dummy gate, respectively, wherein the first sidewall spacer and the second sidewall spacer each include an L-shaped spacer of the first spacer liner and an outer spacer of the second spacer liner.

15. The method of claim 14, wherein depositing the second space liner further includes:
forming a first RDB spacer and a second RDB spacer extending vertically along a set of exposed walls of the RDB dielectric structure above the substrate.

16. The method of claim 14, wherein a source/drain terminal of the set of source/drain terminals associated with the first dummy gate, is formed using epitaxial growth between the first sidewall spacer and the first RDB spacer and extending vertically from the substrate.

17. The method of claim 9, wherein replacing the first dummy gate and the second dummy gate with a metal gate terminal is performed using a replacement metal gate processing.

18. A semiconductor device, the device comprising:
a reduced diffusion break (RDB) structure having a RDB dielectric structure vertically extended into a substrate from a top portion of the inter dielectric layer (IDL), wherein the RDB dielectric structure is configured between a first RDB spacer and a second RDB spacer;
a first sidewall spacer positioned between a first gate terminal and a first source/drain terminal of a first active device, wherein the first sidewall spacer includes a first L-shaped spacer and a first outer spacer, the L-shaped spacer having a base portion horizontally extended from the first gate terminal to the first source/drain terminal and a vertical portion vertically extended parallel to the first outer spacer a top portion of an inter dielectric layer (IDL); and
a second sidewall spacer positioned between a second gate terminal and a second source/drain terminal of a second active device, wherein the second sidewall spacer includes a second L-shaped spacer and a second outer spacer, the second L-shaped spacer having a base portion horizontally extended from the second gate terminal to the second source/drain terminal and a vertical portion vertically extended parallel to the second outer spacer to a top portion of a second IDL.

19. The semiconductor device of claim 18, wherein the RDB dielectric structure has a first reduced width less than a width of the first gate terminal, and wherein the first RDB spacer and the second RDB spacer each have a second reduced width less than a width of the first sidewall spacer.

20. The semiconductor device of claim 18, wherein the RDB structure has a total reduced width that is less than a total width of the first active device.
